(19) United States
(12) Patent Application Publication
(10) Pub. No.: US 2006/0040216 A1
(43) Pub. Date: Feb. 23, 2006

(54) Method of patterning photoresist film

(75) Inventor: Il Ho Lee, Seoul (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor, Inc., Kangnam-ku (KR)

(21) Appl. No.: 11/024,721

(22) Filed: Dec. 30, 2004

(30) Foreign Application Priority Data
Aug. 20, 2004 (KR) 2004-65740

(51) Int. Cl. G03F 7/30

(52) U.S. Cl. 430/329; 430/322

(57) ABSTRACT

A method for patterning a photoresist film provided on a substrate can include exposing the photoresist film, and developing the photoresist film with a developer including a thinner. The method can also include exposing the photoresist film, developing the photoresist film, and cleaning the photoresist film with a cleaning solution including a thinner.

### BACKGROUND OF THE INVENTION

(a) Field of the Invention

The present invention relates to lithography technology, and more particularly, to a method for patterning a photoresist film.

(b) Discussion of the Related Art

Following the recent growth of information and communication technologies, semiconductor device manufacturing continues to rapidly develop. Semiconductor devices have been developed which are highly integrated, miniaturized, and which can obtain higher operational speed. To improve the degree to which the devices are integrated, microlithography has become important.

Lithography technology involves the transfer of patterns formed on a mask to a layer of radiation-sensitive material covering the surface of a substrate. Generally, lithography is carried out through a sequence of processes including a coating process involving the application of a photoresist film, a soft bake process, an alignment process, an exposure process, a post exposure bake (PEB) process, and a development process.

A photoresist has a photosensitivity responding to light, and has a resistance against etching of underlying layers. A photoresist material is divided into a positive photoresist and a negative photoresist. The positive photoresist, having a high resolution and superior resistance against etching, is widely used in a high integration semiconductor process, where reactions such as decomposition, scission of molecular chain, and the like, occur. The use of the positive photoresist results in a greatly increased solubility in a portion exposed to a light which is removed during development process. In the negative photoresist, a crosslinking reaction occurs so that the molecular weight is greatly increased in a portion exposed to a light, and the exposed portion becomes insoluble in the development solution. After development, the unexposed portion is expunged.

In the development process the photoresist changed by exposure is removed so as to transfer the pattern of the mask to the substrate. Generally, a wet development process is used, with an alkaline aqueous solution developer containing Tetra Methyl Ammonium Hydroxide (TMAH) as a main component.

FIGS. 1A through 1D are cross-sectional views illustrating a related art method of patterning a photoresist pattern.

FIG. 1A is a cross-sectional view of a semiconductor substrate 102, which is coated with a photoresist film 104 and is immersed in a developer 106 after an exposure and PEB processes. The photoresist film includes an exposed portion 104b, and an unexposed portion 104a. In a positive photoresist, the exposed portion 104b is expunged during a development process. During the PEB process, a surface of the photoresist film becomes hydrophobic. A developer, containing water as a main component, may not sufficiently contact the hydrophobic surface. Moreover, since the developer has a high surface tension, it is increasingly difficult for the developer to contact the surface of the photoresist film. Thus, a region 108 is formed where the developer and the photoresist film 104 do not contact each other.

FIG. 1B shows the photoresist expunged by the developer 106, and the formation of predetermined patterns. During developing the photoresist film, photoresist residues, such as scum, or other organic contaminants, may be formed. Such scum and organic contaminants can disturb the etching of underlying layers so as to cause pattern failure. Especially, if an underlying layer is a metal wiring layer, the contaminants can form a bridge between wiring lines to cause an electrical short.

FIG. 1C illustrates a process of cleaning a substrate after developing a photoresist film. Generally, a cleaning process is carried out to remove the developer which remains on the substrate after the development process. During the cleaning process, since the substrate 102 is rotated at high speed, empty spaces 116 may be formed between photoresist patterns 115 while a cleaning solution 114 is removed. Further, the empty spaces 116 may become vacuums. Thus, a certain force pushes the photoresist patterns 115 toward a vacuum, as represented by the arrows. As the surface tension of the developer increases, so does the magnitude of the force. Moreover, the force at an edge of the substrate is greater than that at the center of the substrate. Therefore, collapsing of photoresist patterns occurs to a greater degree at the edge of the substrate.

FIG. 1D illustrates photoresist patterns after drying. FIG. 1D shows collapsed photoresist patterns 118 as well as lost photoresist patterns 120 removed during the cleaning or drying process. Since the surface tension of water within the cleaning solution is high, the photoresist patterns are displaced or deformed during drying, as well as cleaning.

Korean patent laid-open publication No. 2003-50175 and Korean registered patent No. 10-272797 describe methods for preventing collapse of photoresist patterns by adding an alcohol to a cleaning solution. The addition of alcohol can prevent photoresist patterns from collapsing, but do not remove photoresist residues such as scum 112.

Furthermore, Korean patent laid-open publication No. 10-2004-5480 describes a method for stripping photoresist patterns with a thinner instead of a developer. However, this method is only available for a photoresist containing a crosslinking agent and cannot prevent collapse of photoresist patterns during cleaning. Further, when 100% thinner is used, photoresist patterns that are to remain will undoubtedly be removed.

### SUMMARY OF THE INVENTION

To address the above-described and other problems, it is an object of the present invention to provide a method for patterning a photoresist film provided on a substrate. The method includes exposing the photoresist film, and developing the photoresist film with a developer including a thinner.

The present invention further provides exposing the photoresist film, developing the photoresist film, and cleaning the photoresist film with a cleaning solution including a thinner.

The present invention still further provides a method for patterning a photoresist film provided on a substrate including a step for exposing the photoresist film, a step for developing the photoresist film, and a step for cleaning the photoresist film. At least one of the step for developing and the step for cleaning uses a solution including a thinner.

It is to be understood that both the foregoing general description of the invention and the following detailed description are exemplary, but are not restrictive of the invention.

### BRIEF DESCRIPTION OF DRAWINGS

The accompanying drawings, which are included to provide a further understanding of the invention and are incorporated in and constitute a part of this application, illustrate aspects of the invention and together with the description serve to explain the principle of the invention.

FIGS. 1A through 1D are cross-sectional views illustrating a related art method of patterning a photoresist pattern.

FIGS. 2A through 2D are cross-sectional views illustrating a method of patterning a photoresist pattern according to the present invention.

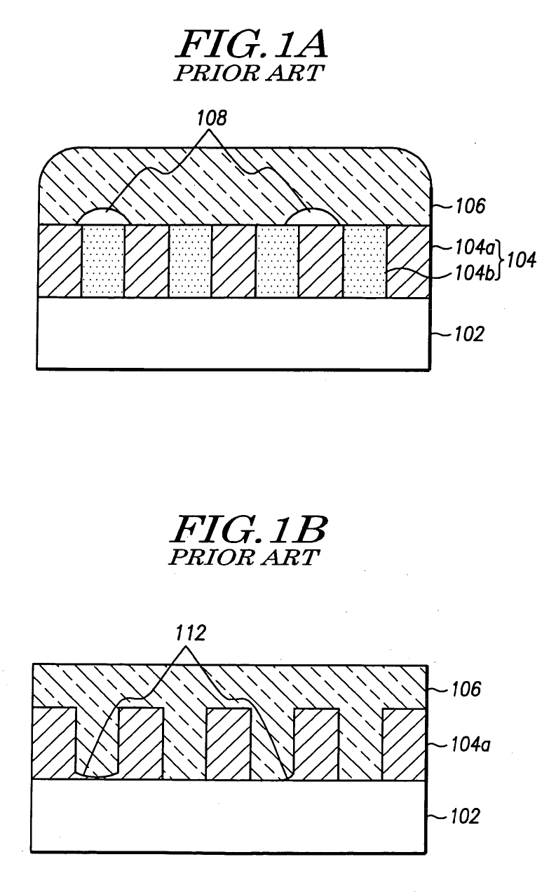

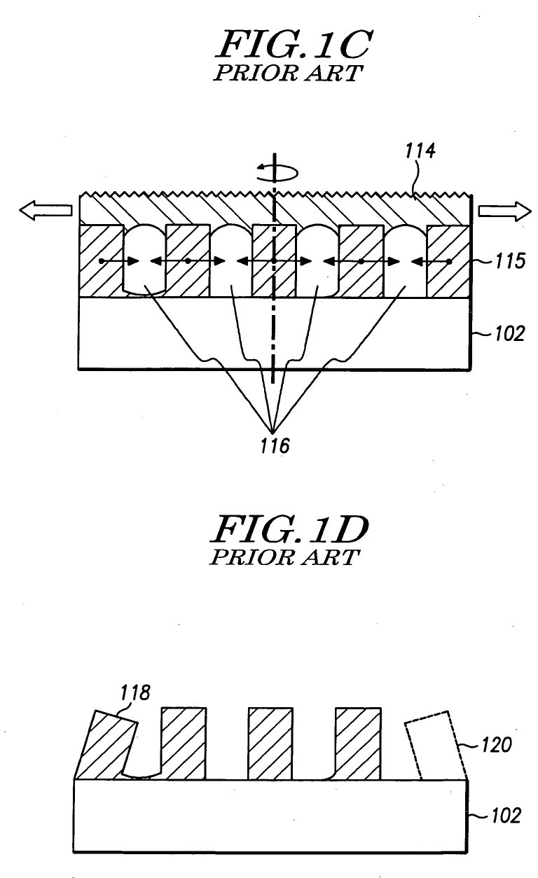

### DETAILED DESCRIPTION OF THE INVENTION

Reference is made in detail to the embodiments of the present invention illustrated in the accompanying drawings. The same reference numbers are used throughout the drawings to refer to the same or similar parts.

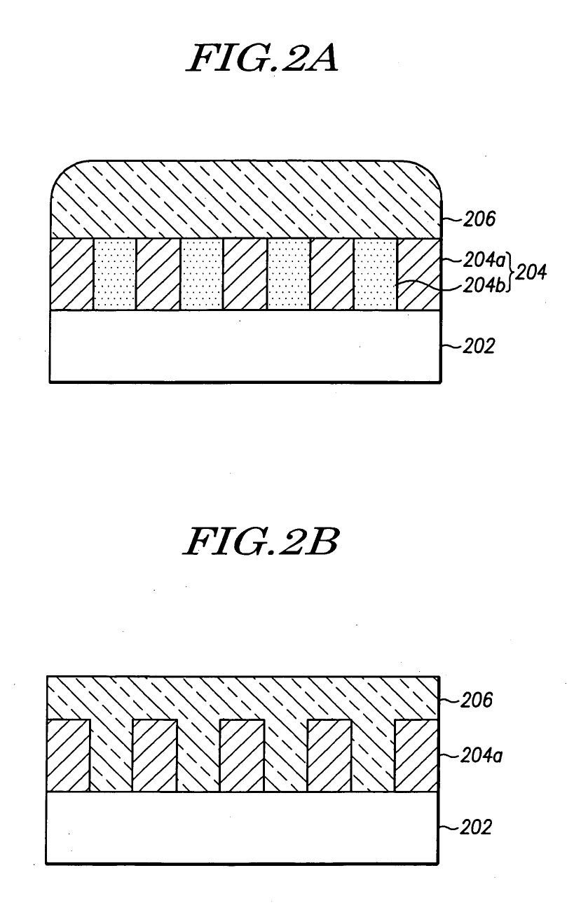

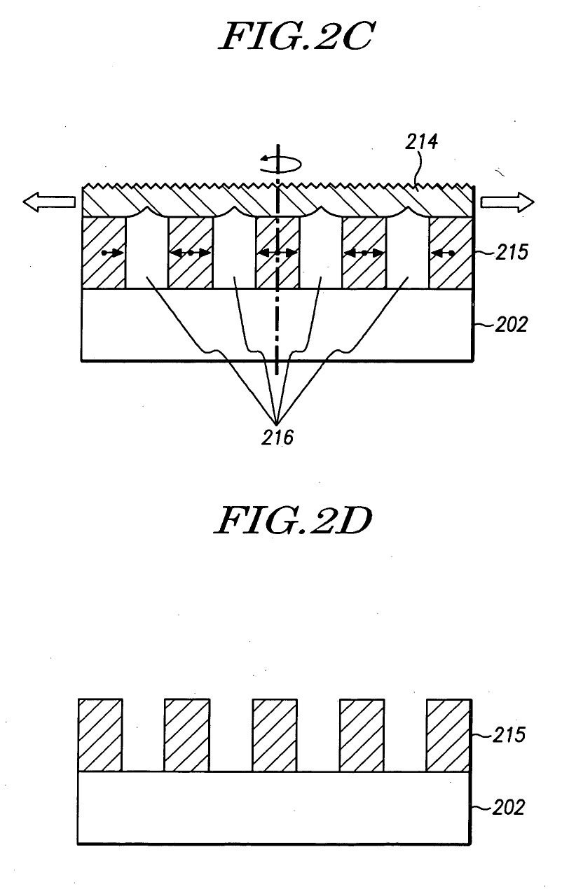

FIGS. 2A through 2D are cross-sectional views illustrating a method of patterning a photoresist film according to the present invention.

FIG. 2A shows a semiconductor substrate 202 provided with one or more predetermined structures, which is coated with a photoresist film 204. A developer 206 is applied to the photoresist film 204 after exposure and one or more PEB (post exposure bake) processes are performed on the photoresist film 204. The photoresist film 204 includes an exposed portion 204b and an unexposed 204a.

In a positive photoresist, the exposed portion 204b is expunged or removed during a development process by the developer 206. Preferably, the developer 206 includes an alkaline aqueous solution containing TMAH as a main component. The developer 206 can include a relatively small amount of thinner (for example, less than 5 vol %) to reduce a surface tension of the developer 206, such that sufficient contact occurs between the developer 206 and the photoresist film 204. Preferably, the thinner has a good volatility, low velocity of dissolution of the photoresist film 204, and/or a low surface tension. If the velocity of dissolution of the photoresist film 204 is too high or the volatility is not good, photoresist patterns may be undesirably removed. In this case, a proportion of the thinner can be lowered. The thinner can be one or more known thinners. Preferred thinners include ether or ether acetate including propylene glycol ether, propylene glycol ether acetate, ethylene glycol monoethyl ether acetate (EGMEA), and propylene glycol monomethyl ether acetate, and ester including methyl acetate, ethyl acetate, butyl acetate, and ethyl lactate (EL).

Examples of light sources available for an exposure process include g-line (436 nm), i-line (365 nm), KrF (248 nm), ArF (193 nm), EUV (13 nm), X-ray, an electron beam and an ion beam. Because collapsing of photoresist patterns frequently occurs during formation of micro-patterns having a high aspect ratio and a small gap between patterns, the effects of the addition of the thinner are conspicuous in a process of formation of micro-patterns.

FIG. 2B shows the substrate in which the exposed photoresist 204b is expunged by the developer 206. Sufficient contact between the developer 206 and the photoresist film 204 can prevent occurrence of photoresist residues (e.g., scum). However, photoresist residues may result from various causes. Therefore, the occurrence of photoresist residues can be effectively prevented by the addition of the thinner.

FIG. 2C illustrates a cleaning process carried out after developing the photoresist film. During the cleaning process, the substrate 202 rotates at a high speed so that empty spaces 216 between photoresist patterns 204 become vacuums instantaneously. As a result, a certain force is applied on photoresist patterns 215 toward a vacuum. If the surface tension of a cleaning solution 214 is low, the force is decreased. The surface tension of the cleaning solution 214 can be lowered by the addition of a relatively small amount of thinner (for example, less than 5 vol %) into water (Deionized water) in the cleaning solution 214. Thus, collapsing of photoresist patterns 215 can be prevented. Further, by adding the thinner, photoresist residues (e.g., scum) and organic contaminants can be removed. Preferably, the thinner added to the cleaning solution 214 is the same as that added to the developer 206.

After cleaning, the substrate 202 is subjected to a drying process. Collapsing of photoresist patterns 215 can occur during the drying process as well as a developing process. During the drying process, photoresist patterns 215 may collapse due to the surface tension of the cleaning solution 214 that remains between photoresist patterns 215. As shown in FIG. 2D, photoresist patterns 215 that resist collapsing can be obtained by adding the thinner to the cleaning solution 214.

In the above-explained embodiment, the thinner is added into both the developer and the cleaning solutions. Alternatively, the thinner can be added into either one of the developer or the cleaning solution. Furthermore, alcohol or acetone, along with the thinner, can be added into the developer and/or the cleaning solutions. In this case, the thinner removes photoresist residues, and the alcohol or acetone decreases the surface tension of the developer or the cleaning solutions.

The present application incorporates by reference in its entirety Korean Patent Application No. P2004-65740, filed in the Korean Patent Office on Aug. 20, 2004.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for patterning a photoresist film provided on a substrate, comprising:
exposing the photoresist film; and
developing the photoresist film with a developer including a thinner.

2. The method according to claim 1, wherein the step of developing uses at least one of ether, ether acetate and ester as the thinner.

3. The method according to claim 1, wherein the step of developing uses at least one of ethylene glycol monoethyl acetate (EGMEA), propylene glycol monomethyl ether acetate (PGMEA), and ethyl lactate (EL) as the thinner.

4. The method according to claim 1, wherein the step of developing uses an amount of the thinner at most about 5% of the volume of the developer.

5. The method according to claim 1, wherein the step of developing uses at least one alcohol and acetone in the developer.

6. A method for patterning a photoresist film provided on a substrate, comprising:
exposing the photoresist film;
developing the photoresist film; and
cleaning the photoresist film with a cleaning solution including a thinner.

7. The method according to claim 6, wherein the step of cleaning uses at least one of ether, ether acetate and ester as the thinner.

8. The method according to claim 6, wherein the step of cleaning uses at least one of ethylene glycol monoethyl acetate (EGMEA), propylene glycol monomethyl ether acetate (PGMEA), and ethyl lactate (EL) as the thinner.

9. The method according to claim 6, wherein the step of cleaning uses an amount of the thinner at most about 5% by volume of the cleaning solution.

10. The method according to claim 6, wherein the step of cleaning uses at least one of alcohol and acetone in the cleaning solution.

11. A method for patterning a photoresist film provided on a substrate, comprising:
step for exposing the photoresist film;
step for developing the photoresist film; and
step for cleaning the photoresist film,
wherein at least one of the step for developing and the step for cleaning uses a solution including a thinner.

12. The method according to claim 11, wherein the at least one of the step for developing and the step for cleaning uses at least one of ether, ether acetate and ester as the thinner.

13. The method according to claim 11, wherein the at least one of the step for developing and the step for cleaning uses at least one of ethylene glycol monoethyl acetate (EGMEA), propylene glycol monomethyl ether acetate (PGMEA), and ethyl lactate (EL) as the thinner.

14. The method according to claim 11, wherein the at least one of the step for developing and the step for cleaning uses an amount of the thinner at most about 5% by volume of the solution.

15. The method according to claim 11, wherein the at least one of the step for developing and the step for cleaning uses at least one of alcohol and acetone in the solution.

16. The method according to claim 11, wherein the step for developing uses a developer.

17. The method according to claim 11, wherein the step for cleaning uses a cleaning solution.
